(19) United States
(12) Patent Application Publication
(10) Pub. No.: US 2025/0329673 A1
(43) Pub. Date: Oct. 23, 2025

(54) Direct Wire Reveal Package

(71) Applicant: Apple Inc., Cupertino, CA (US)

(72) Inventors: Kwan-Yu Lai, Campbell, CA (US); Myung Jin Yim, San Jose, CA (US); Jun Zhai, Cupertino, CA (US); Young Doo Jeon, San Jose, CA (US); Jeng-Wen P. Chen, Campbell, CA (US); Raymundo M. Camenforte, San Jose, CA (US); DaeByoung Kang, Sunnyvale, CA (US)

(21) Appl. No.: 18/638,582

(22) Filed: Apr. 17, 2024

(51) Int. Cl. H01L 23/00; H01L 23/498; H01L 25/00; H01L 25/065; H01L 25/10; H10B 80/00

(52) U.S. Cl. CPC H01L 24/05; H01L 23/49827; H01L 23/49833; H01L 24/06; H01L 24/13; H01L 24/14; H01L 25/0652; H01L 25/0657; H01L 25/105; H01L 25/50; H10B 80/00; H01L 24/03; H01L 24/11; H01L 24/16; H01L 24/32; H01L 24/33; H01L 2224/033; H01L 2224/05015; H01L 2224/05016; H01L 2224/05144; H01L 2224/05147; H01L 2224/05555; H01L 2224/05556; H01L 2224/05573; H01L 2224/05644; H01L 2224/05647; H01L 2224/06132; H01L 2224/06135; H01L 2224/113; H01L 2224/13014; H01L 2224/13016; H01L 2224/13144; H01L 2224/13147; H01L 2224/14132; H01L 2224/14135; H01L 2224/16235; H01L 2224/32145; H01L 2224/33181; H01L 2225/06562; H01L 2225/1041; H01L 2924/1436; H01L 2924/14511

(57) ABSTRACT

Electronic packages and package-on-package structures are described. In an embodiment, an electronic package include multiple staircased dies and multiple vertical wire bonds encapsulated by a molding layer, where the multiple vertical wire bonds protrude from a top surface of the molding layer so that the vertical wire bonds stand proud above a top surface of the molding layer.

### BACKGROUND

### Field

Embodiments described herein relate to semiconductor packaging. More particularly, embodiments relate to the stacking of memory dies.

### Background Information

The current market demand for portable and mobile electronic devices such as mobile phones, personal digital assistants (PDAs), digital cameras, portable players, gaming, and other mobile devices requires the integration of more performance and features into increasingly smaller spaces. As a result, various multiple-die packaging solutions such as system in package (SiP) and package on package (POP) have become more popular to meet the demand for higher die/component density devices. In one implementation, memory dies or packages such as dynamic random-access memory (DRAM), which is generally considered a volatile memory, and/or non-volatile memory die or package, such as flash (e.g. NAND), are stacked on top of a logic die or package (e.g., application-specific integrated circuit (ASIC)) or system on chip (SoC). As the market for portable and mobile electronic devices advances larger memory capability is required of the memory die or package. In one implementation, multiple memory dies are stacked vertically to increase the memory in a memory die package.

### SUMMARY

Electronic package and package-on-package (“PoP”) structures are described. In an embodiment, an electronic package includes a multiple staircased dies, multiple vertical wire bonds, and a molding layer that encapsulates the multiple staircased dies and the multiple vertical wire bonds, where the wire bonds extend vertically from a contact ledge of the multiple stacked dies and protrude from the molding layer to stand proud above a top surface of the molding layer. In an embodiment, an electronic package includes multiple staircased dies, multiple vertical interconnect bars, and a molding layer that encapsulates the multiple staircased dies and the multiple vertical interconnect bars. In an embodiment, a package-on-package structure includes a at least a first electronic package a second electronic package, a support structure, a vertical interconnect array bar, and a molding layer to that encapsulates the first electronic package, the second electronic package, the support structure and the vertical interconnect array bar, where the vertical interconnect array bar extends from a top surface of the first electronic package to a top surface of the second electronic package.

### BRIEF DESCRIPTION OF THE DRAWINGS

FIG. 1A is a schematic cross-sectional side view illustration of an electronic package with vertical wire bonds that stand proud in accordance with embodiments.

FIG. 1B is a schematic cross-sectional side view illustration of an electronic package with vertical wire bonds that stand proud and solder bumps in accordance with embodiments.

FIG. 1C is a schematic cross-sectional side view illustration of an electronic package with vertical wire bonds and a package routing layer in accordance with embodiments.

FIG. 1D is a schematic top view illustration of an electronic package with vertical wire bonds that stand proud in accordance with embodiments.

FIG. 2 is a flow chart illustrating a process for forming an electronic package with vertical wire bonds that stand proud in accordance with an embodiment.

FIGS. 3A-3D are schematic cross-sectional side view illustrations for a process for forming an electronic package with vertical wire bonds that stand proud in accordance with embodiments.

FIG. 4A is a schematic cross-sectional side view illustration of an electronic package with vertical interconnect bars in accordance with embodiments.

FIG. 4B is a schematic cross-sectional side view illustration of an electronic package with vertical interconnect bars in accordance with embodiments.

FIG. 5 is a flow chart illustrating a process for forming an electronic package with vertical interconnect bars in accordance with embodiments.

FIGS. 6A-6E are schematic cross-sectional side view illustrations for a process for forming an electronic package with vertical interconnect bars in accordance with embodiments.

FIGS. 7A-7D are schematic cross-sectional side view illustrations of a package-on-package structure in accordance with embodiments.

FIGS. 8A-8D are schematic cross-sectional side view illustrations of a package-on-package structure with neighboring electronic packages in accordance with embodiments.

FIGS. 9A-9C are schematic cross-sectional side view illustrations of neighboring staircased dies in accordance with embodiments.

FIGS. 10A-10C are schematic cross-sectional side view illustrations of neighboring staircased dies in accordance with embodiments.

### DETAILED DESCRIPTION

Embodiments describe electronic packages and package-on-package (“POP”) structures that include multiple dies (e.g., memory dies), where the multiple dies may be vertically stacked in a staircase fashion (e.g., staircasing, etc.). In one aspect, it has been observed that the testing of stacked memory packages typically occurs at wafer level prior to package singulation and after a package routing layer (e.g., redistribution layer) has been formed over a reconstituted wafer including the stacked memory dies. For example, this may be attributed to wafer-level processes being utilized for formation of the package routing layer. However, it has been observed that testing such packages at wafer level may be problematic since the probe cards used for testing such packages have a rectangular array of probes that may be better suited for testing rectangular shaped panels rather than circular wafers. In an embodiment, an electronic package includes multiple staircased dies and multiple vertical wire bonds encapsulated in a molding layer, where the multiple vertical wire bonds extend from a contact ledge of the multiple staircased dies and protrude from a top surface of the molding layer so that the vertical wire bonds stand proud above the top surface of the molding layer. Thus, the memory dies can be stacked onto panels rather than wafers since it is not necessary for a redistribution layer to be formed prior to testing. As such, testing may occur on these protruding wire bonds at panel level, rather than at wafer level, where the vertical wire bonds may then undergo further fabrication for subsequent packaging processes (e.g., flip chip, integrated fan-out, etc.). Such a fabrication sequence can improve throughput for testing, and potentially reduce fabrication costs by moving the packaging sequence to a panel-level facility rather than wafer-level facility, and potentially remove necessity for the package routing layer (e.g., redistribution layer) altogether depending upon the product. In an embodiment, similar structures can be fabricated with vertical interconnect bars (e.g., through-silicon via bars, through-glass via bars, etc.) rather than vertical wire bonds, which may allow for finer pitch designs. In an embodiment, package-on-package structures may be assembled through the modular scaling of the electronic packages described, where the electronic packages themselves may be staircased and supported by one or more support structures.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

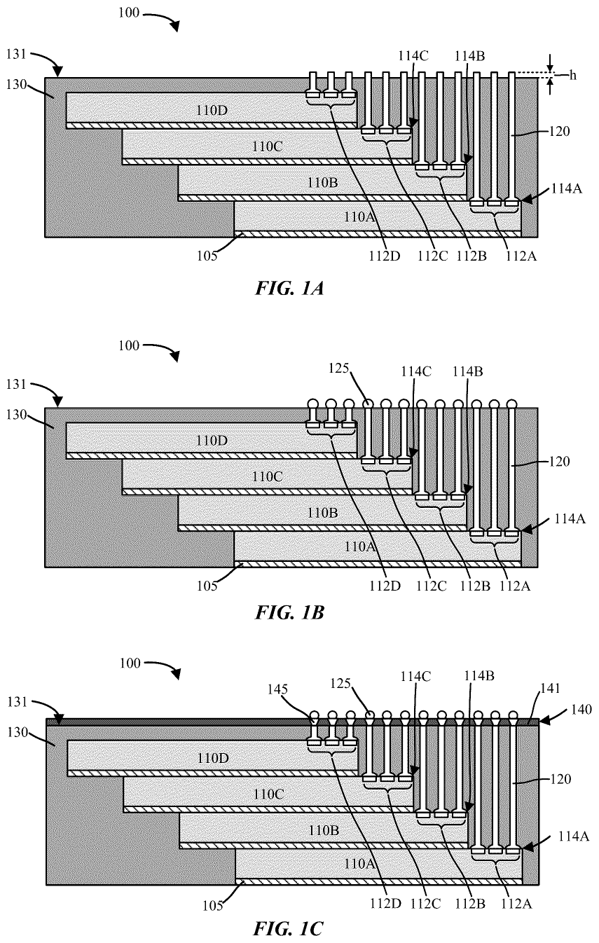

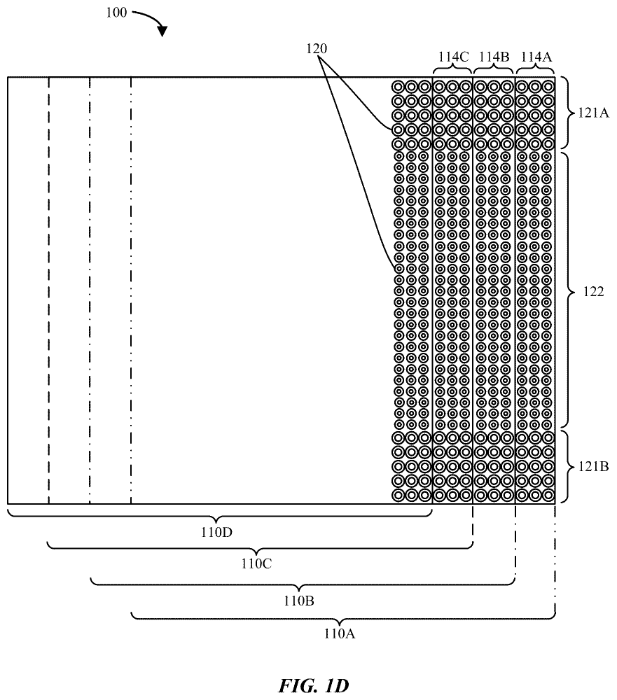

Referring now to FIG. 1A, a cross sectional side view illustration is provided of an electronic package with multiple vertical wire bonds that stand proud in accordance with embodiments. Package 100 may include multiple staircased dies 110 and multiple vertical wire bonds 120 encapsulated by molding layer 130. The multiple staircased dies 110 may include various types of digital, analog or mixed-signal integrated circuits. In an embodiment, the multiple staircased dies are memory dies or chips (e.g., DRAM, NOT-AND (“NAND”), etc.). In addition, an adhesive layer (e.g., die attach film, etc.) may be applied to the backside of a die for attaching the die to an underlying die or substrate (e.g., carrier substrate, etc.). In the example of FIG. 1A, multiple staircased dies 110 include dies 110A, 110B, 110C, 110D vertically stacked in a “staircase” fashion so as to create contact ledges 114A, 114B, and 114C, respectively, where the dies may be attached to each other by adhesive layer 105. Further, due to the staircasing of the dies, the contact ledges become the only exposed areas where back end of line (“BEOL”) build-up structures may be exposed. As such, the die routing/contact layers of the multiple dies may be designed to extend to these exposed areas at the edges of the dies. For example, in FIG. 1A, multiple staircased dies 110 include die contact pads 112A on contact ledge 114A, die contact pads 112B on contact ledge 114B, die contact pads 112C on contact ledge 114C, and die contact pads 112D, where the die contact pads may connect the dies to other locations within the package.

In further reference to FIG. 1A, the multiple vertical wire bonds 120 extend vertically through a thickness of molding layer 130 and protrude through a top surface 131 of molding layer 130 so that the multiple vertical wire bonds 120 stand proud above top surface 131. Further, the height that the multiple vertical wire bonds 120 protrude above the top surface 131 may vary based on factors related to memory die testing (e.g., type of instrumentation, pitch design, etc.). In the example of FIG. 1A, the multiple vertical wire bonds 120 protrude above top surface 131 of molding layer 130 by a height, h, where h may be in the range of 5-10 microns although other heights are contemplated. In this way, the vertical wire bonds that protrude/stand proud above a top surface of the molding layer may be contacted by a test probe to enable testing at strip level (rather than at wafer level) so that the packages may be shipped as known good packages. In some embodiments, the standing proud vertical wire bonds may remain intact above the top surface of the molding layer, such as when package 100 and another package (e.g., system-on-chip, etc.) may be encapsulated together in another molding layer. In other embodiments, the standing proud vertical wire bonds may undergo further fabrication for subsequent packaging processes (e.g., flip chip, integrated fan-out, etc.). For example, a grinding operation may remove the protruding vertical wire bonds where optional solder bumps (e.g., solder bumps 125) may then be placed such as the example of FIG. 1B, or an optional package routing layer 140 may be formed on top surface 131 such as the example of FIG. 1C, where optional package routing layer 140 may include dielectric layers 141, one or more metal redistribution lines, and plated vias (e.g., plated via 145). In further reference to FIG. 1C, the plated vias may connect to the multiple vertical wire bonds 120, where the plated vias may then be bumped with solder bumps (e.g., solder bumps 125).

Referring now to FIG. 1D, a schematic top view illustration is provided of an electronic package with vertical wire bonds that stand proud in accordance with embodiments. In the example of FIG. 1D, the multiple staircased dies 110 include die 110B over die 110A, die 110C over die 110B, and die 110D over die 110C. The multiple staircased dies 110 expose contact ledges 114A, 114B, and 114C, where the multiple vertical wire bonds 120 may be bonded. Further, the multiple vertical wire bonds 120 may include direct access regions 121A, 121B and an array region 122. Direct access regions 121A, 121B may include vertical wire bonds with a greater or coarser pitch size and/or wider diameter than the wire bonds located in array region 122. In one embodiment, direct access regions 121A, 121B include vertical wire bonds with a 90-micron pitch. In this way, the embodiments described eliminate the need for specialty instrumentation or probes for the testing of the memory dies, which allows for standardized instrumentation and probes to directly contact the coarser pitch size and/or larger diameter vertical wire bonds located in direct access regions 121A, 121B so that the testing of memory dies may be accomplished at the strip level.

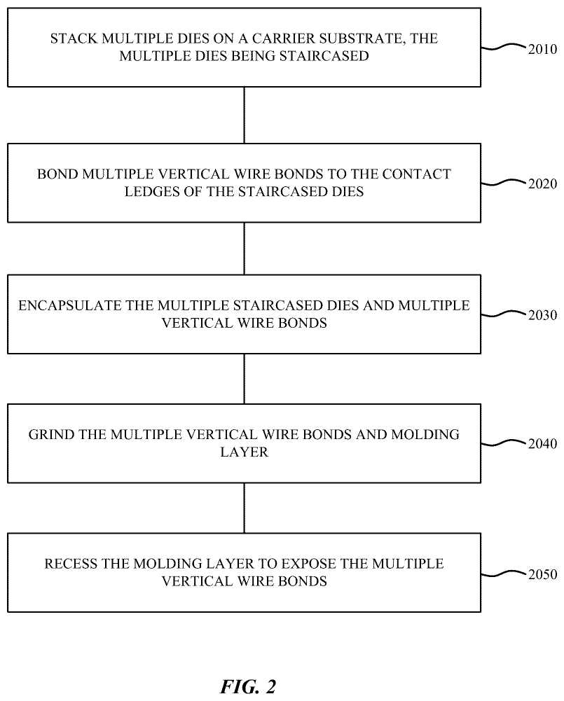

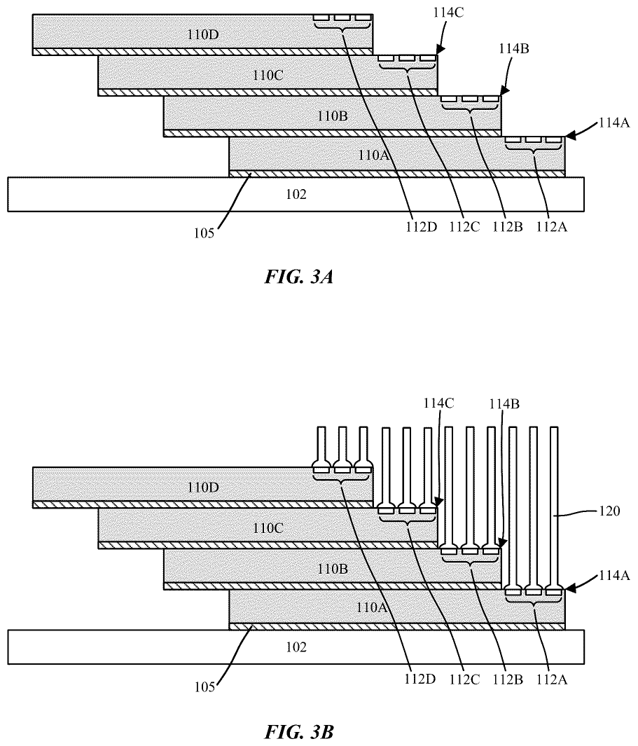

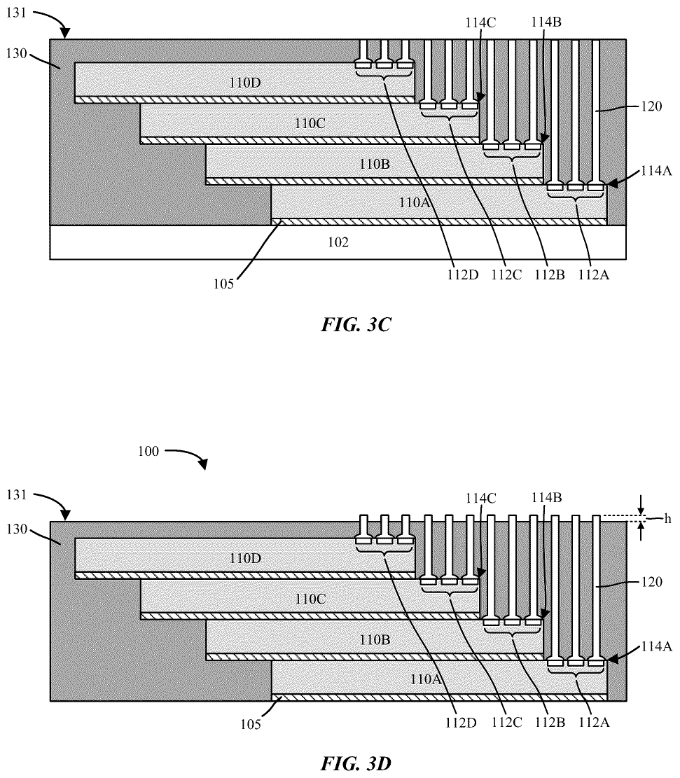

Referring now to FIG. 2 and FIGS. 3A-3D, FIG. 2 is a flow chart illustrating a process of forming an electronic package with vertical wire bonds that stand proud in accordance with an embodiment; FIGS. 3A-3D are schematic cross-sectional side view illustrations for a process for forming an electronic package with vertical wire bonds that stand proud in accordance with an embodiment. In the interest of clarity and conciseness, the process flow of FIG. 2 is discussed concurrently with FIGS. 3A-3D. As shown in FIG. 3A, at operation 2010 multiple dies may be stacked in a staircase fashion to form multiple staircased dies 110 on carrier substrate 102, which may be a suitable substrate, such as a semiconductor wafer, glass, metal plate, etc. More specifically, the carrier substrate 102 may be panel shaped so that the packaging sequence can be performed outside of a wafer facility. In particular, a first die 110A may be attached to carrier substrate 102 with adhesive layer 105, followed by the staircasing of second die 110B, third die 110C and fourth die 110D, where adhesive layer 105 is applied between the staircased dies. In addition, the staircasing of the dies exposes die contact pads 112A on contact ledge 114A, die contact pads 112B on contact ledge 114B, die contact pads 112C on contact ledge 114C and die contact pads 112D.

As shown in FIG. 3B, at operation 2020 multiple vertical wire bonds 120 are bonded to the multiple staircased dies 110. In particular, multiple vertical wire bonds 120 are bonded to die contact pads 112A, 112B, 112C, and 112D and drawn vertically away. In an embodiment, the multiple vertical wire bonds 120 are gold wires. In the alternative, copper wires may be utilized where the protruding heights of the copper wires (see FIG. 3D) are treated to protect against oxidation (e.g., organic solderability preservative (“OSP”), electro-less gold plating (“e-less ENEPIG”), etc.). Further, the multiple vertical wire bonds 120 may include wires with different diameters and/or attached at different pitches. Referring back to FIG. 1C, the vertical wire bonds located in direct access regions 121A, 121B may have a larger diameter and/or larger pitch (e.g., 90-micron pitch) than the vertical wire bonds located in array region 122 so as to create a larger surface for the memory die testing instrumentation (e.g., probes) to contact the vertical wire bonds during testing. At operation 2030, FIG. 3C shows the encapsulation of the multiple staircased dies 110 and multiple vertical wire bonds 120, where encapsulation may be accomplished with a molding layer, such as molding layer 130, or other suitable insulator gap fill material such as oxide, nitride, etc. This may be followed by the grinding down of molding layer 130 and the multiple vertical wire bonds 120 at operation 2040, where the multiple vertical wire bonds 120 may become flush with (or even recessed below) top surface 132 of molding layer 130. In such instances, the multiple vertical wire bonds may not have enough exposure to be able to make electrical contact with the memory die testing instrumentation, which may result in unreliable tests or the inability to conduct tests altogether.

As shown in FIG. 3D, at operation 2050 the molding layer may be recessed to expose the multiple vertical wire bonds so that the multiple vertical wire bonds may stand proud above a top surface of the molding layer. For example, the molding layer may be recessed by a dry plasma etching process or other suitable process for removing molding layer 130 so that the memory die testing instrumentation can make direct contact with the multiple vertical wire bonds 120 located in direct access regions 121A, 121B. In one embodiment, molding layer 130 is dry plasma etched so that the height, h, of the multiple vertical wire bonds above top surface 131 of molding layer 130 is approximately 5-10 microns. After recessing molding layer 130, memory die testing may be performed to determine known good packages, followed by further fabrication processes so that that package 100 can be mounted onto a module substrate (e.g., printed circuit board, etc.). In some embodiments, after a grinding operation optional solder bumps, such as solder bumps 125 illustrated in FIG. 1B, may then be placed on package 100, followed by the removal of carrier substrate 102 and singulation. In other embodiments, after a grinding operation an optional package routing layer, such as package routing layer 140 in FIG. 1C, may be formed over package 100 before the removal of carrier substrate 102. In such instances, package routing layer 140 may include one or more dielectric layers 141 that may be formed by standard deposition techniques (e.g., spin coating, spray coating, physical vapor deposition, chemical vapor deposition, etc.), one or more optional metal redistribution lines formed of copper or other suitable material, and plated vias 145 formed of copper or other suitable material that connect to the multiple vertical wire bonds, where the plated vias may be bumped with solder bumps 125, as illustrated in FIG. 1C.

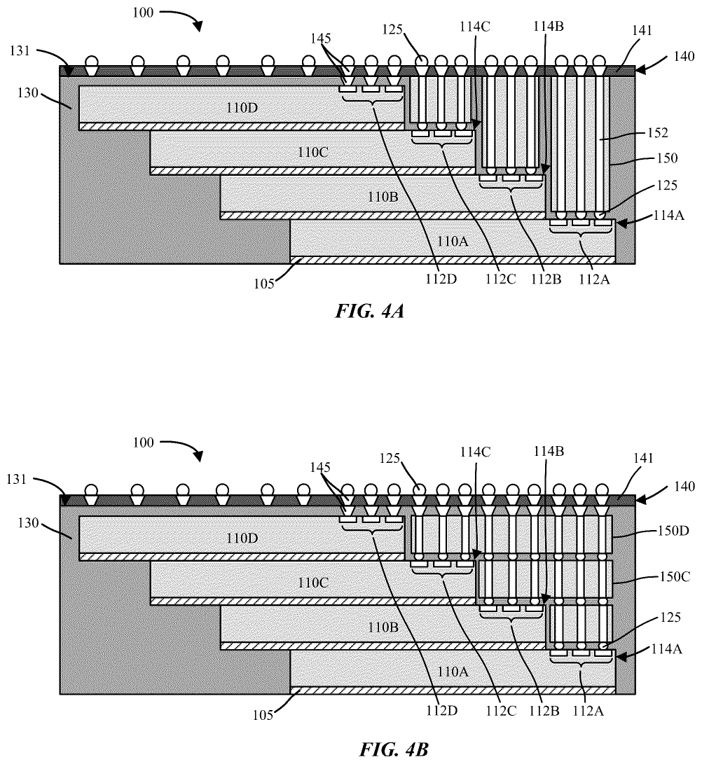

Referring now to FIGS. 4A-4B, a cross sectional side view illustration is provided of an electronic package with vertical interconnect bars in accordance with embodiments. Unlike the example of FIG. 1A in which package 100 included vertical wire bonds, in the example of FIGS. 4A-4B package 100 does not include vertical wire bonds, but rather includes multiple vertical interconnect bars 150. In the example of FIG. 4A-4B, the multiple staircased dies 110 include dies 110A, 110B, 110C, 110D vertically stacked to create contact ledges 114A, 114B, and 114C, respectively, where the dies are attached to each other by adhesive layer 105. In addition, the multiple staircased dies 110 and multiple vertical interconnect bars 150 may be encapsulated by molding layer 130. Further, the multiple vertical interconnect bars 150 may be formed of suitable material (e.g., silicon, glass, etc.) and may include vias (e.g., vias 152) plated with copper or other suitable material to form a through-silicon via bar, a through-glass via bar, etc., where the vertical interconnect bars may be structured so that the pitch of the vertical interconnect bar is the same as the pitch of the memory dies. In some embodiments, the multiple vertical interconnect bars 150 may extend vertically through a thickness of the molding layer from the contact ledge to a top surface of the molding layer, which may include an optional package routing layer. For example, in FIG. 4A, multiple vertical interconnect bars 150 connect to die contact pads 112A on contact ledge 114A, die contact pads 112B on contact ledge 114B, and die contact pads 112C on contact ledge 114C, where the multiple vertical interconnect bars 150 may be bonded to the die contact pads at the contact ledge (e.g., solder bumps, anisotropic conductive film, etc.). In the example of FIG. 4A, the multiple vertical interconnect bars 150 connect to the die contact pads through solder bumps 125 and extend through a thickness of molding layer 130 to package routing layer 140. In such instances, the height of vertical interconnect bars may vary based on the distance between the die contact pad and the package routing layer, for example, and the width of vertical interconnect bars may be less than the width of the contact ledge upon which the vertical interconnect bars are bonded. For die contact pads 112D, rather than vertical interconnect bars, plated vias (e.g., plated vias 145) may be formed in molding layer 130 to provide a connection between die contact pads 112D and a subsequent layer formed on top surface 131 of molding layer 130 (e.g., package routing layer 140, etc.). In one example, package routing layer 140 may be formed over molding layer 130 and include one or more dielectric layers 141, one or more optional metal redistribution lines (not illustrated), and plated vias 145, where the plated vias may be bumped with solder bumps 125. In further reference to FIG. 4A, some plated vias may be stacked, such as the plated vias 145 located above die contact pads 112D, where the lower plated vias may be located in molding layer 130 and the upper plated vias may be located in package routing layer 140.

In reference to FIG. 4B, in other embodiments, the vertical interconnect bars themselves may be staircased, where a height of the vertical interconnect bars may be approximately the same height as an adjacent die and the width of the vertical interconnect bars may span across multiple contact ledges. For example, in FIG. 4B, the vertical interconnect bar adjacent to die 110C (vertical interconnect bar 150C) spans across contact ledges 114B and 114A, and the vertical interconnect bar adjacent to die 110D (vertical interconnect bar 150D) spans across contact ledges 114C, 114B and 114A. In addition, since the height of the vertical interconnect bars may be approximately the same height as an adjacent die, the vertical interconnect bars do not extend to top surface 131 of molding layer 130. As such, in addition to plated vias 145 located above die contact pads 112 in molding layer 130, package 100 also includes plated vias 145 located above vertical interconnect bar 150D in molding layer 130, as illustrated in FIG. 4B. In this way, plated vias 145 may provide a connection between the die contact pads of the multiple staircased dies and a subsequent layer formed on top surface 131 of molding layer 130 (e.g., package routing layer 140, etc.). In one example, package routing layer 140 may be formed over molding layer 130 and include one or more dielectric layers 141, one or more optional metal redistribution lines (not illustrated), and plated vias 145, where the plated vias may be bumped with solder bumps 125. In further reference to FIG. 4B, some plated vias may be stacked, such as vias 145 located above die contact pads 112D and above vertical interconnect bar 150D, where the lower plated vias may be located in molding layer 130 and the upper plated vias may be located in package routing layer 140.

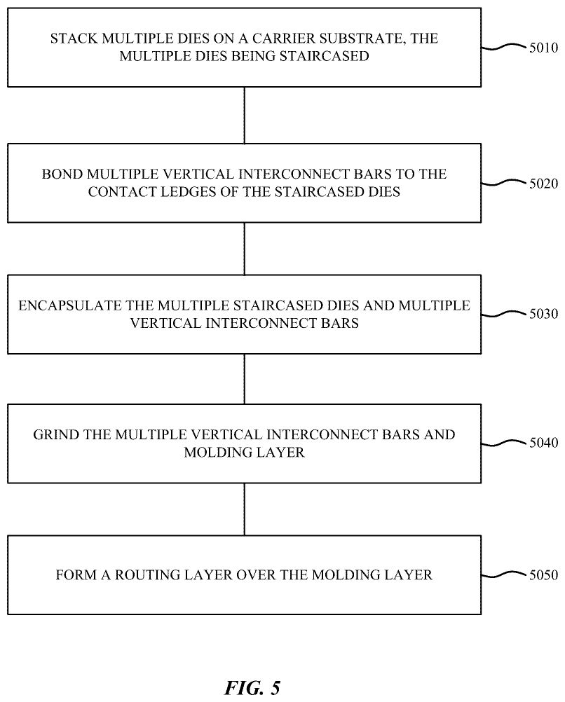

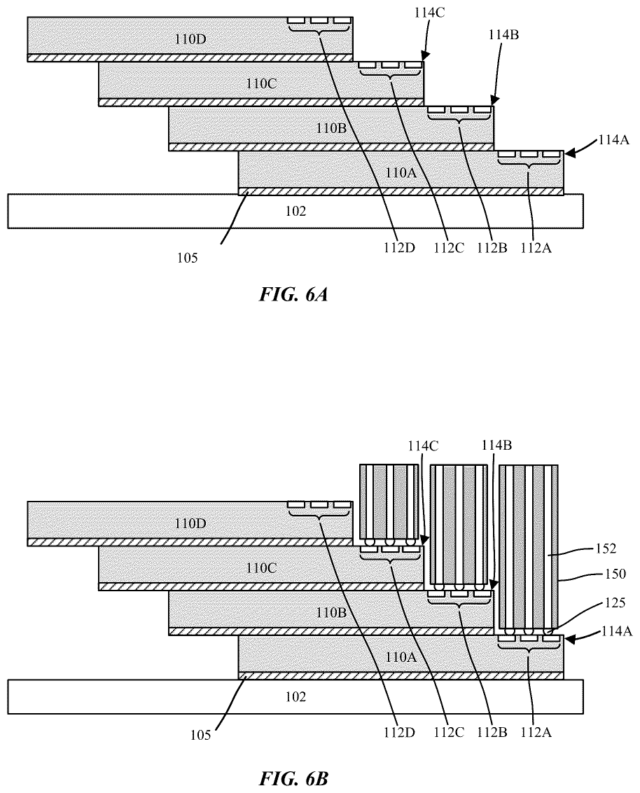

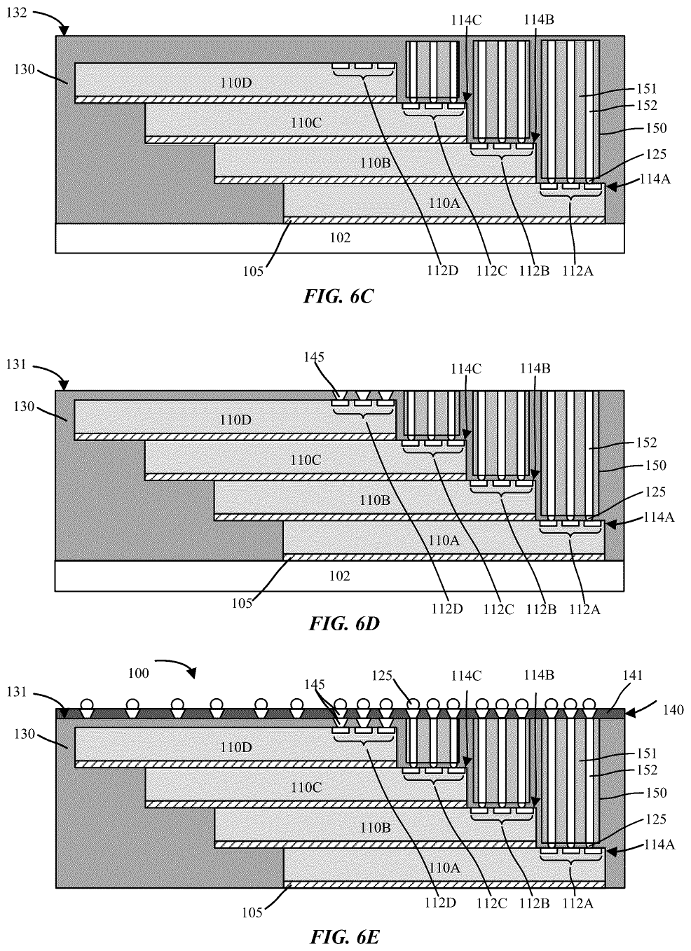

Referring now to FIG. 5 and FIGS. 6A-3D, FIG. 5 is a flow chart illustrating a process for forming an electronic package with vertical interconnect bars in accordance with an embodiment; FIGS. 6A-6D are schematic cross-sectional side view illustrations for a process for forming an electronic package with vertical interconnect bars in accordance with an embodiment. In the interest of clarity and conciseness, the process flow of FIG. 5 is discussed concurrently with FIGS. 6A-6D. As shown in FIG. 6A, at operation 5010 multiple dies may be stacked in a staircase fashion to form multiple staircased dies 110 on carrier substrate 102, which may be a suitable substrate, such as a semiconductor wafer, glass, metal plate, etc. In particular, a first die 110A is attached to carrier substrate 102 with adhesive layer 105, followed by the staircasing of second die 110B, third die 110C and fourth die 110D where adhesive layer 105 is applied between the staircased dies. In addition, the staircasing of the dies exposes die contact pads 112A on contact ledge 114A, die contact pads 112B on contact ledge 114B, die contact pads 112C on contact ledge 114C and die contact pads 112D.

As shown in FIG. 6B, at operation 5020 multiple vertical interconnect bars 150 are bonded to the multiple staircased dies 110. The multiple vertical interconnect bars 150 may be through-silicon via bars, through-glass via bars, etc. Further, the multiple vertical interconnect bars 150 may be bonded to the die contact pads of the multiple stacked dies by thermocompression bonding, compression bonding, mass reflow, anisotropic conductive film or any other suitable bonding technique. In the example of FIG. 6B, multiple vertical interconnect bars 150 connect to the die contact pads 112A, 112B, and 112C through solder bumps 125. At operation 2030, FIG. 6C shows the encapsulation of multiple staircased dies 110 and multiple vertical interconnect bars 150 to form top surface 132, where encapsulation may be accomplished with a molding layer, such as molding layer 130, or other suitable insulator gap fill material such as oxide, nitride, etc. At operation 2040, FIG. 6D shows the grinding down of molding layer 130 and the multiple vertical interconnect bars 150 from top surface 132 to a desired package height, such as top surface 131, which may expose vias 152 of multiple vertical interconnect bars 150. Further, plated vias 145 may be formed in molding layer 130 over die contact pads 112D, where plated vias 145 may be formed of copper or other suitable material and connect to die contact pads 112D. In other embodiments, in which the height of vertical interconnect bars 150 is approximately the same height as an adjacent die, such as vertical interconnect bar 150D in FIG. 4B, plated vias 145 may be additionally formed in molding layer 130 over the vertical interconnect bar. At operation 5050, FIG. 6E shows package routing layer 140 formed over top surface 131 of molding layer 130, followed by the removal of carrier substrate 102. In such instances, package routing layer 140 may include one or more dielectric layers 141 formed by standard deposition techniques (e.g., spin coating, spray coating, physical vapor deposition, chemical vapor deposition, etc.), one or more optional metal redistribution lines formed of copper or other suitable material (not illustrated), and plated vias 145, where plated vias may be formed over vias 152 of the multiple vertical interconnect bars 150 as well as the plated vias 145 located in molding layer 130 (where vias 145 may be stacked above die contact pads 112D). Such plated vias 145 in package routing layer 140 may then be bumped with solder bumps 125.

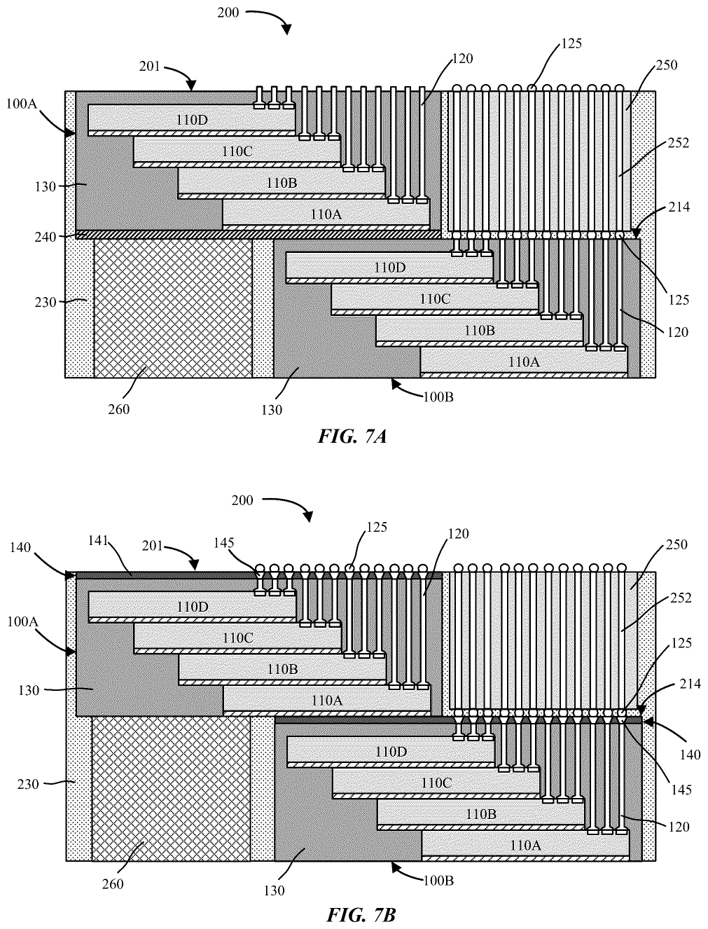

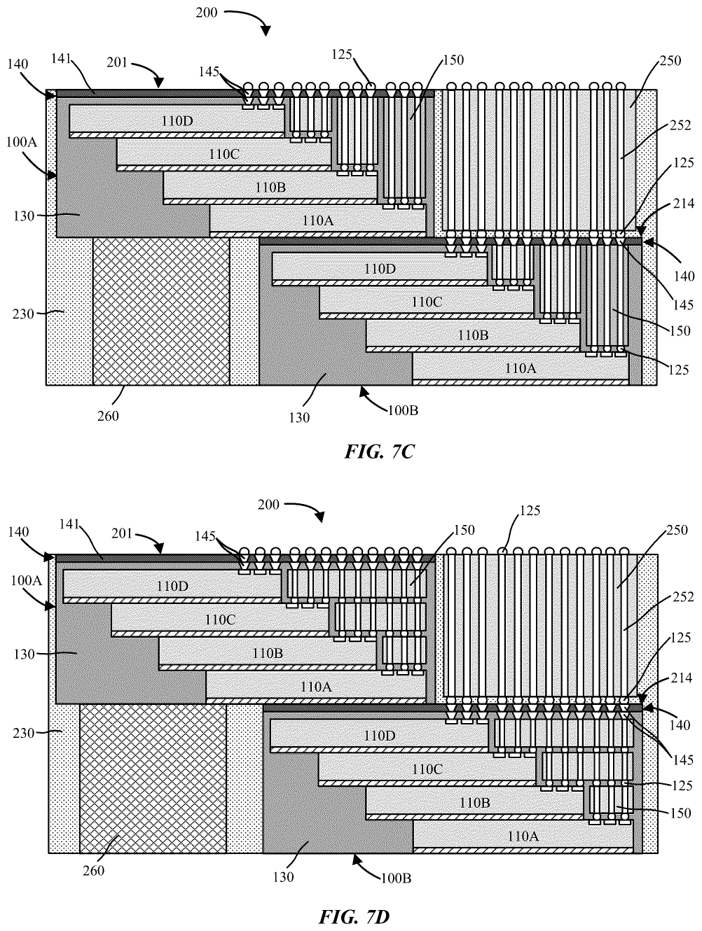

Referring now to FIGS. 7A-7D, schematic cross-sectional side view illustrations are provided of a package-on-package structure in accordance with embodiments. Electronic packages may be stacked to form package-on-package structures to increase the number of memory dies in a singular package. For example, in FIG. 7A, package 200 includes packages 100A and 100B, support structure 260 and vertical interconnect array bar 250 encapsulated by molding layer 230. Package 100A (upper package) and package 100B (lower package) may be vertically stacked in a staircase fashion, where support structure 260 may be located adjacent to the lower package (e.g., package 100B) and below the upper package (e.g., package 100A) in order to provide support for the upper package, where adhesive layer 240 (e.g., die attach film) may be applied between packages. Further, the staircasing of packages 100A and 100B may create a contact ledge 214, where vertical interconnect array bar 250 (e.g., through-silicon via array bar, through-glass via array bar, etc.) may extend from contact ledge 214 through a thickness of molding layer 230 to a top surface 201 of package 200. In such instances, the multiple vertical wire bonds 120 of package 100B (lower package) may include solder bumps 125 (similar to the example of FIG. 1B) to bond the multiple vertical wire bonds 120 of package 100B to vias 252 of vertical interconnect array bar 250. Further, the multiple vertical wire bonds 120 of package 100A (upper package) may stand proud above top surface 201 of package 200 so that memory die testing may be performed, after which the multiple vertical wire bonds 120 of package 100A may undergo further fabrication processes. For example, after testing, a grinding operation may remove the protruding vertical wire bonds where optional solder bumps (e.g., solder bumps 125) may then be placed on top surface 201 package 200 similar to the example illustrated in FIG. 1B, or an optional package routing layer (e.g., package routing layer 140) may be formed over top surface 201 of package 200 similar to the example illustrated in FIG. 1C.

In further reference to FIGS. 7B-7D, schematic cross-sectional side view illustrations are provided for variations to the package-on-package structure described in FIG. 7A. For example, in FIG. 7B, package 200 includes packages 100A and 100B, where packages 100A and 100B include multiple vertical wire bonds 120 and package routing layer 140 similar to package 100 described in FIG. 1C. In FIG. 7C, package 200 includes packages 100A and 100B, where packages 100A and 100B include multiple vertical interconnect bars 150 (rather than multiple vertical wire bonds 120) similar to package 100 described in FIG. 4A. In such embodiments, a height of the multiple vertical interconnect bars 150 extends vertically from the die contact pads of the stacked dies, through a thickness of the molding layer 130, and to package routing layer 140. In FIG. 7D, package 200 includes packages 100A and 100B, where packages 100A and 100B include multiple vertical interconnect bars 150 (rather than multiple vertical wire bonds 120) similar to package 100 described in FIG. 4B. In such embodiments, a height of the multiple vertical interconnect bars 150 is approximately the same height as the height of an adjacent die, where the vertical interconnect bars may span across multiple contact ledges of the die. Further, in the examples of FIGS. 7B-7D, vertical interconnect array bar 250 may extend from contact ledge 214, through a thickness of molding layer 230, and to top surface 201 of package 200. In such instances, solder bumps 125 placed on package routing layer 140 of package 100B (lower package) may bond vertical interconnect array bar 250 to package 100B.

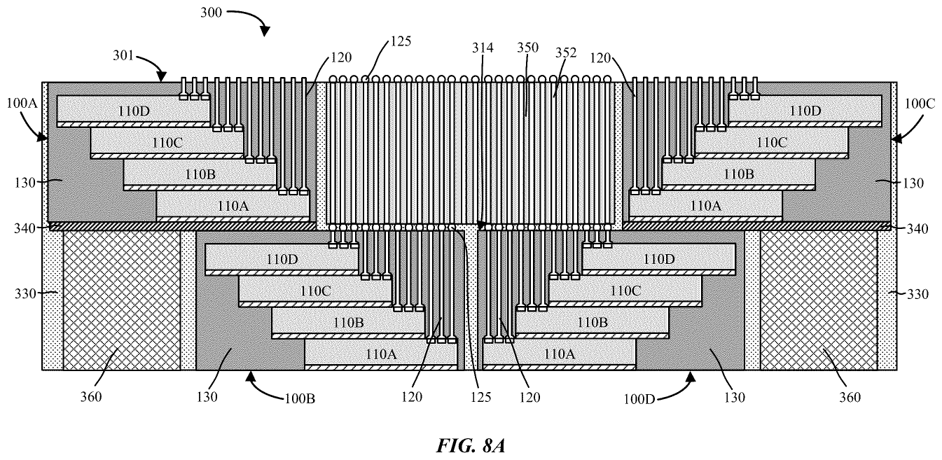

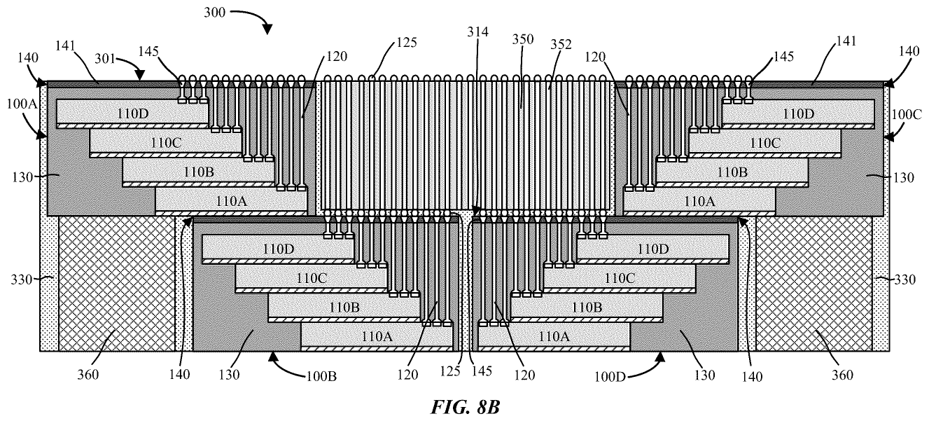

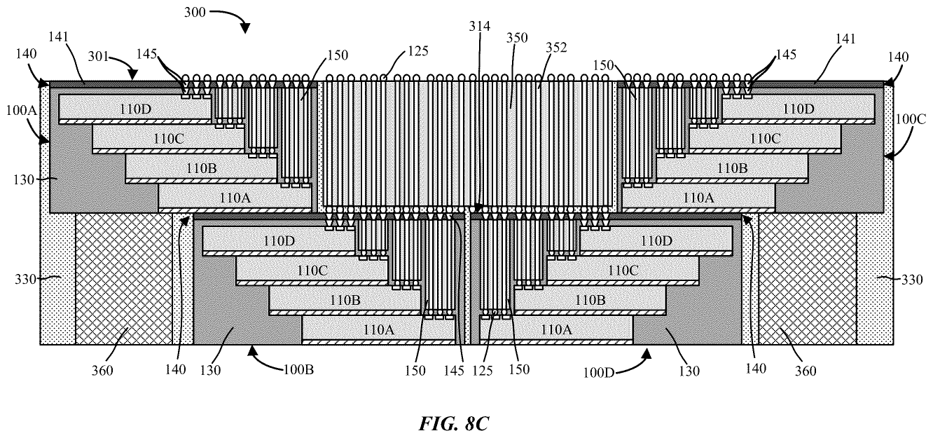

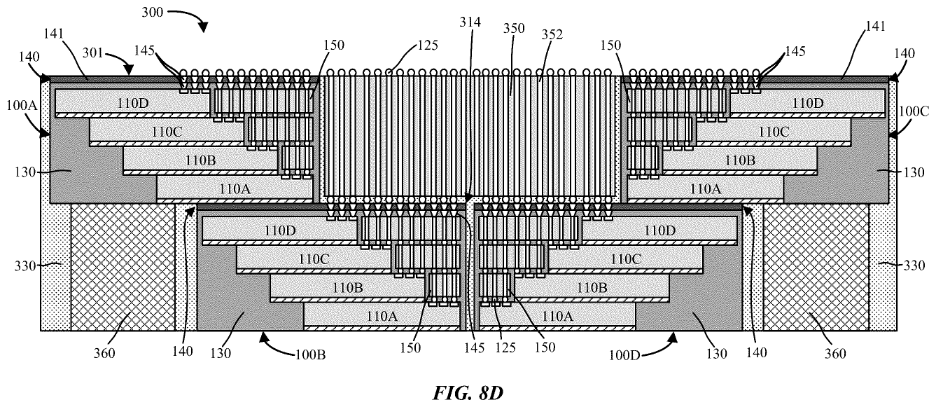

Referring now to FIGS. 8A-8D, schematic cross-sectional side view illustrations are provided of neighboring stacked electronic packages in accordance with embodiments. The examples described in FIGS. 8A-8D show variations to the examples described in FIGS. 7A-7D in that the set of staircased packages in FIGS. 7A-7D may be positioned “face-to-face” in that the neighboring staircased packages face each other so as to form a “V”-shaped arrangement of the memory dies. For example, in FIG. 8A, package 300 includes packages 100A, 100B, 100C and 100D, support structures 360 and vertical interconnect array bar 350 encapsulated by molding layer 330. Packages 100A and 100B may be vertically stacked in a staircase fashion and may face packages 100C and 100D that may also be vertically stacked in a staircase fashion, where the memory dies form a “V”-shaped arrangement within package 300. Further, package 300 may include support structures 360 that may be located adjacent to the lower packages (e.g., packages 100B and 100D) and below the upper packages (e.g., packages 100A and 100C) in order to provide support for the upper packages, where adhesive layer 240 (e.g., die attach film) may be applied between packages. Further, the face-to-face positioning of packages 100A and 100B with packages 100C and 100D may create a contact ledge 314, where vertical interconnect array bar 350 (e.g., through-silicon via bar, through-glass via bar, etc.) may extend from contact ledge 314 through a thickness of molding layer 330 to a top surface 301 of package 300. In such instances, the multiple vertical wire bonds 120 of the lower packages, (packages 100B and 100D) may include solder bumps 125 (similar to the example of FIG. 1B) to bond the multiple vertical wire bonds 120 of packages 100B and 100D to vias 352 of vertical interconnect array bar 350. Further, the multiple vertical wire bonds 120 of the upper packages (packages 100A and 100C) may stand proud above top surface 201 of package 200 so that memory die testing may be performed, after which the multiple vertical wire bonds 120 of packages 100A and 100C may undergo further fabrication processes. For example, after testing, a grinding operation may remove the protruding vertical wire bonds where optional solder bumps (e.g., solder bumps 125) may then be placed on top surface 301 of package 300 similar to the example illustrated in FIG. 1B, or an optional package routing layer (e.g., package routing layer 140) may be formed over top surface 301 of package 300 similar to the example illustrated in FIG. 1C.

In further reference to FIGS. 8B-8D, schematic cross-sectional side view illustrations are provided for variations to the neighboring stacked electronic packages described in FIG. 8A. For example, in FIG. 8B, package 300 includes packages 100A, 100B, 100C and 100D that include multiple vertical wire bonds 120 and package routing layer 140 similar to package 100 described in FIG. 1C. In FIG. 8C, package 300 includes packages 100A, 100B, 100C and 100D that include multiple vertical interconnect bars 150 (rather than multiple vertical wire bonds 120) similar to package 100 described in FIG. 4A. In FIG. 8D, package 300 includes packages 100A, 100B, 100C and 100D that include multiple vertical interconnect bars 150 (rather than multiple vertical wire bonds 120) similar to package 100 described in FIG. 4B. In addition, in the examples of FIGS. 8B-8D, vertical interconnect array bar 350 may span across the lower packages, such as packages 100B and 100D, and extend from contact ledge 314, through a thickness of molding layer 330, and to a top surface 301 of package 300. In particular, solder bumps 125 placed on package routing layer 140 of the lower packages (packages 100B and 100D) may bond vertical interconnect array bar 350 to packages 100B and 100D.

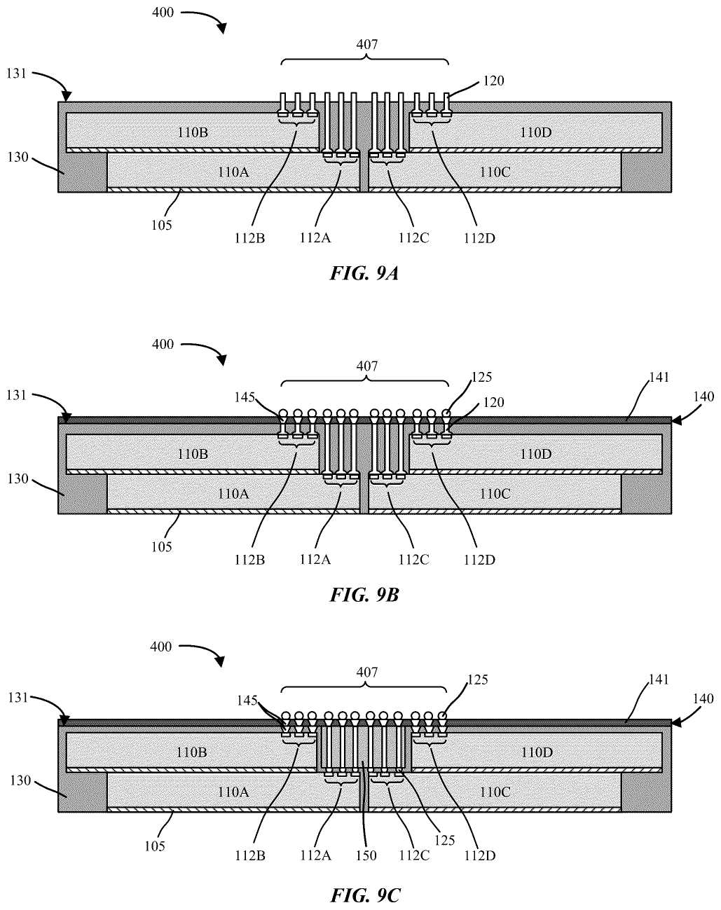

Referring now to FIGS. 9A-9C, schematic cross-sectional side view illustrations are provided of neighboring staircased dies in accordance with embodiments. The examples described in FIGS. 9A-9C include multiple staircased dies stacked two-high rather than four-high as described in FIG. 1A, for example. In addition, the two-high staircased dies may be “face-to-face” with another set of two-high staircased dies in that the neighboring staircased dies face each other so as to form a “V”-shaped arrangement of the memory dies. For example, in FIG. 9A, package 400 includes multiple staircased dies 110 and multiple vertical wire bonds 120 encapsulated by molding layer 130. The multiple staircased dies 110 includes dies 110A, 110B, 110C and 110D, which include die contact pads 112A, 112B, 112C and 112D, respectively. In addition, an upper die, such as die 110B, may be staircased on top of a lower die, such as die 110A, where die 110A and 110B may be attached by adhesive layer 105. Further, an upper die, such as die 110D, may be staircased on top of a lower die, such as die 110C, where die 110C and 110D may be attached by adhesive layer 105. In the example of FIG. 9A, the 110A/110B stack may be arranged or positioned face-to-face with the 110C/110D stack so as to form a “V”-shaped arrangement of the memory dies, where the multiple vertical wire bonds may be grouped toward a central location of package 400. In particular, multiple vertical wire bonds 120 may be bonded to die contact pads 112A of die 110A, die contact pads 112B of die 110B, die contact pads 112C of die 110C, and die contact pads 112D of die 110D, where the multiple vertical wire bonds are located at central location 407. Further, the multiple vertical wire bonds 120 stand proud above top surface 131 of molding layer 130, similar to the embodiment described in FIG. 1A, so that memory die testing may be performed, after which the multiple vertical wire bonds 120 of package 400 may undergo further fabrication processes. For example, after testing, a grinding operation may be performed where solder bumps (e.g., solder bumps 125) may then be placed on package 400 similar to the example illustrated in FIG. 1B, or an optional package routing layer (e.g., package routing layer 140) may be formed over package 400 as illustrated in the example of FIG. 9B. In such instances, package routing layer 140 may include one or more dielectric layers 141, one or more optional metal redistribution lines (not illustrated), and plated vias 145 that connect to the multiple vertical wire bonds 120, where solder bumps 125 may then be placed on the plated vias 145. FIG. 9C illustrates a variation of FIG. 9A where the multiple vertical interconnect bars 150 may be utilized in place of the multiple vertical wire bonds, similar to the embodiment of FIG. 4A, for example. In such instances, vertical interconnect bar 150 spans across the lower dies (e.g., 110A and 110C) and extends through a thickness through a thickness of molding layer 130, and to a top surface 131 of molding layer 130. In particular, solder bumps 125 may be placed on die contact pads of the lower dies, such as die contact pads 112A of die 110A and die contact pads 112C of die 110C, to bond the vertical interconnect bar to the lower dies.

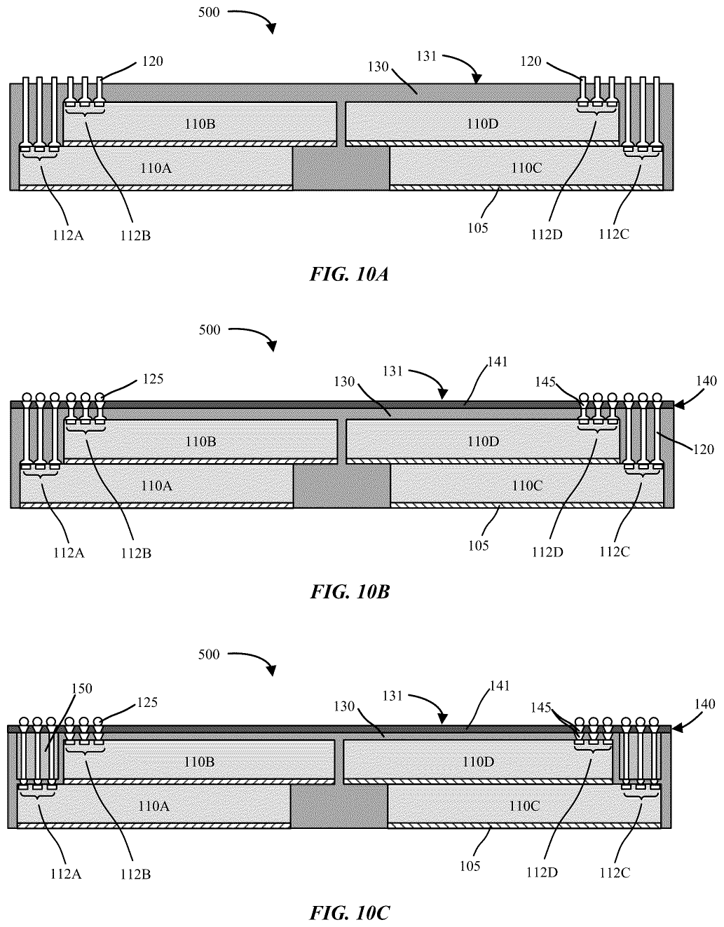

Referring now to FIGS. 10A-10C, schematic cross-sectional side view illustrations are provided of neighboring staircased dies in accordance with embodiments. The examples described in FIGS. 10A-10C are similar to the examples described in FIGS. 9A-9C in that the multiple dies are stacked two-high rather than four-high. However, the examples described in FIGS. 10A-10C differ from the examples described in FIGS. 9A-9C in that the staircased dies of FIGS. 10A-10C may be positioned or arranged “back-to-back” to each other so that the vertical connections reside at the edges of the package, as opposed to the face-to-face embodiment in FIGS. 9A-9C where the vertical connections are grouped in the middle of the package. For example, in FIG. 10A, package 500 includes multiple staircased dies 110 and multiple vertical wire bonds 120 encapsulated by molding layer 130. The multiple staircased dies 110 may include dies 110A, 110B, 110C and 110D, which include die contact pads 112A, 112B, 112C and 112D, respectively. In addition, die 110B may be staircased on top of die 110A, where die 110A and 110B may be attached by adhesive layer 105. Further, die 110D may be staircased on top of die 110C, where die 110C and die 110D may be attached by adhesive layer 105. In the example of FIG. 10A, the 110A/110B stack is back-to-back with the 110C/110D stack so that the multiple vertical wire bonds 120 may be located toward the edges of package 500. In particular, multiple vertical wire bonds 120 may be bonded to die contact pads 112A of die 110A, die contact pads 112B of die 110B, die contact pads 112C of die 110C, and die contact pads 112D of die 110D. Further, the multiple vertical wire bonds 120 may stand proud above top surface 131 of molding layer 130, similar to the embodiment described in FIG. 1A, for example, so that memory die testing may be performed, after which the multiple vertical wire bonds 120 of package 500 may undergo further fabrication processes. For example, after testing, a grinding operation may be performed where solder bumps (e.g., solder bumps 125) may then be placed on package 500 similar to the example illustrated in FIG. 1B, or an optional package routing layer (e.g., package routing layer 140) may be formed over package 500 as illustrated in the example of FIG. 10B. In such instances, package routing layer 140 may include one or more dielectric layers 141, one or more optional metal redistribution lines (not illustrated), and plated vias 145 that connect to the multiple vertical wire bonds 120, where solder bumps 125 may then be placed on the plated vias 145. FIG. 10C illustrates a variation of FIG. 10A where multiple vertical interconnect bars 150 may be utilized in place of the multiple vertical wire bonds, similar to the embodiment of FIG. 4A, for example. In such instances, the multiple vertical interconnect bars 150 may extend through a thickness of molding layer 130 to a top surface 131 of molding layer 130. In particular, solder bumps 125 may be placed on die contact pads of the lower dies, such as die contact pads 112A of die 110A and die contact pads 112C of die 110C, to bond the multiple vertical interconnect bars to the lower dies.

In utilizing the various aspects of the embodiments, it would become apparent to one skilled in the art that combinations or variations of the above embodiments are possible for stacked memory packages and package on package structures thereof. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic package comprising:
multiple staircased dies, the multiple staircased dies including multiple contact ledges;
multiple vertical wire bonds bonded to the multiple contact ledges; and
a molding layer that encapsulates the multiple staircased dies and the multiple vertical wire bonds, wherein the multiple vertical wire bonds extend past a top surface and stand proud above the molding layer.

2. The electronic package of claim 1, wherein the multiple staircased dies are memory dies.

3. The electronic package of claim 1, wherein the multiple vertical wire bonds include a first region with a first pitch size and a second region with a second pitch size, the first pitch size being greater than the second pitch size.

4. The electronic package of claim 1, wherein the multiple staircased dies include a first set of dies that includes a first upper die attached to a first lower die, and a second set of dies that includes a second upper die and a second lower die, the first set of dies and the second set of dies being positioned so that the multiple vertical wire bonds are located at a central location on the electronic package.

5. The electronic package of claim 1, wherein the multiple staircased dies include a first set of dies that includes a first upper die attached to a first lower die, and a second set of dies that includes a second upper die and a second lower die, the first set of dies and the second set of dies being positioned so that the multiple vertical wire bonds are located at a first edge and a second edge on the electronic package.

6. An electronic package comprising:
multiple staircased dies, the multiple staircased dies including multiple contact ledges;
multiple vertical interconnect bars bonded to the multiple contact ledges; and
a molding layer that encapsulates the multiple staircased dies and the multiple vertical interconnect bars.

7. The electronic package of claim 6, wherein the multiple staircased dies are memory dies.

8. The electronic package of claim 6, wherein a height of the multiple vertical interconnect bars extend from the multiple contact ledges to a top surface of the molding layer, and a width of the multiple vertical interconnect bars is less than a width of the multiple contact ledges.

9. The electronic package of claim 6, wherein a height of the multiple vertical interconnect bars is less than a height of an adjacent die, and a width of the multiple vertical interconnect bars spans across one or more contact ledges of the multiple contact ledges.

10. The electronic package of claim 6, wherein the multiple staircased dies include a first set of dies that includes a first upper die attached to a first lower die, and a second set of dies that includes a second upper die and a second lower die, the first set of dies and the second set of dies being positioned so that the multiple vertical interconnect bars are located at a central location on the electronic package.

11. The electronic package of claim 6, wherein the multiple staircased dies include a first set of dies that includes a first upper die attached to a first lower die, and a second set of dies that includes a second upper die and a second lower die, the first set of dies and the second set of dies being positioned so that the multiple vertical interconnect bars are located at a first edge and a second edge on the electronic package.

12. A package-on-package structure comprising:
multiple staircased electronic packages including at least a first set of electronic packages, the first set of electronic packages including a first upper electronic package and a first lower electronic package;
one or more support structures, the one or more support structures including at least a first support structure located adjacent to the first lower electronic package and below the first upper electronic package;
a vertical interconnect array bar; and
a molding layer that encapsulates the multiple staircased electronic packages, the one or more support structures and the vertical interconnect array bar.

13. The package-on-package structure of claim 12, wherein the multiple staircased electronic packages each include multiple staircased dies, the multiple staircased dies being memory dies.

14. The package-on-package structure of claim 12, wherein the first upper electronic package and the first lower electronic package each include:
multiple staircased dies, the multiple staircased dies including multiple contact ledges;
multiple vertical wire bonds bonded to the multiple contact ledges; and
a molding layer that encapsulates the multiple staircased dies and the multiple vertical wire bonds, wherein the multiple vertical wire bonds extend past a top surface and stand proud above the molding layer.

15. The package-on-package structure of claim 14, further comprising a second set of electronic packages including a second upper electronic package and a second lower electronic package, the second upper electronic package and the second lower electronic package including:
multiple staircased dies, the multiple staircased dies including multiple contact ledges;
multiple vertical wire bonds bonded to the multiple contact ledges; and
a molding layer that encapsulates the multiple staircased dies and the multiple vertical wire bonds, wherein the multiple vertical wire bonds extend past a top surface and stand proud above the molding layer.

16. The package-on-package structure of claim 15, wherein the first set of electronic packages and the second set of electronic packages are positioned face-to-face so that a top surface of the first lower electronic package and a top surface of the second lower electronic package form a package contact ledge, wherein the vertical interconnect array bar spans the package contact ledge.

17. The package-on-package structure of claim 12, wherein the first upper electronic package and the first lower electronic package each include:
multiple staircased dies, the multiple staircased dies including multiple contact ledges;
multiple vertical interconnect bars bonded to the multiple contact ledges; and
a molding layer that encapsulates the multiple staircased dies and the multiple vertical interconnect bars.

18. The package-on-package structure of claim 17, further comprising a second set of electronic packages including a second upper electronic package and a second lower electronic package, the second upper electronic package and the second lower electronic package including:
multiple staircased dies, the multiple staircased dies including multiple contact ledges;
multiple vertical interconnect bars bonded to the multiple contact ledges; and
a molding layer that encapsulates the multiple staircased dies and the multiple vertical interconnect bars.

19. The package-on-package structure of claim 18, wherein the first set of electronic packages and the second set of electronic packages are positioned face-to-face so that a top surface of the first lower electronic package and a top surface of the second lower electronic package form a package contact ledge, wherein the vertical interconnect array bar spans the package contact ledge.

20. The package-on-package structure of claim 12, further comprising multiple package routing layers formed over each of the multiple staircased electronic packages.
